(19) United States
(12) Patent Application Publication
(10) Pub. No.: US 2024/0400858 A1
(43) Pub. Date: Dec. 5, 2024

(54) HIGH CRACK THRESHOLD PLANARIZING COATINGS AND PROCESSES TO FILL WIDE AND DEEP TRENCHES FOR SILICONE WAFERS

(71) Applicant: HONEYWELL INTERNATIONAL INC., Charlotte, NC (US)

(72) Inventors: Hong Min Huang, Cupertino, CA (US); Songyuan Xie, E. Palo Alto, CA (US); Desaraju Varaprasad, Dublin, CA (US)

(21) Appl. No.: 18/664,268

(22) Filed: May 14, 2024

Related U.S. Application Data
(60) Provisional application No. 63/468,442, filed on May 23, 2023.

(51) Int. Cl. C09D 183/08; C08G 77/08; C08G 77/26; C09D 7/20; H01L 21/3105

(52) U.S. Cl. CPC C09D 183/08; C08G 77/08; C08G 77/26; C09D 7/20; H01L 21/31051

(57) ABSTRACT

The present disclosure provides a high crack threshold curable composition comprising at least one polysiloxane resin, a solvent medium, and a crosslinker. The solvent medium may further include at least one solvent having a boiling point greater than 100° C. and at least one solvent having a boiling point less than 100° C.

### CROSS-REFERENCE TO RELATED APPLICATION

This application claims the benefit under 35 U.S.C. § 119 (e) of Provisional Application No. 63/468,442, filed May 23, 2024, which is herein incorporated by reference in its entirety.

### FIELD

The present disclosure relates generally to planarizing materials, and, in particular, to planarizing silicone-based compositions for coating semiconductor and display devices.

### BACKGROUND

In advanced semiconductor manufacturing, for example microprocessors, memory devices, and displays employing light emitting diodes, there is a need for dielectric materials which can be spin-coated onto a surface of a device to fill deep spaces or gaps between device structures to provide a relatively planar surface suitable for subsequent device layer processing.

It is important that such dielectric materials be crack resistant at thicknesses that allow the material to completely fill trenches of the semiconductor devices while exhibiting thermal stability at elevated temperatures.

### SUMMARY

The present disclosure provides a composition for planarizing a substrate, comprising at least one polysiloxane resin, a solvent medium, and a crosslinker including a siloxane compound. Each of the at least one polysiloxane resin comprises the reaction product of one or more monomers of the following formulas:

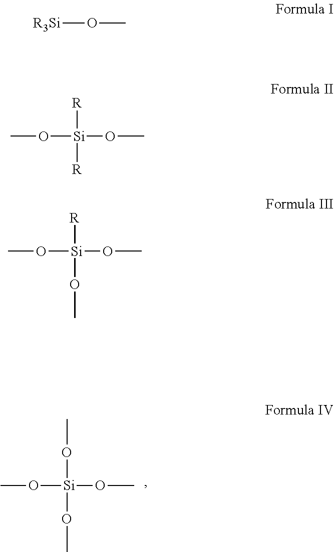

wherein R₁ and R₂ are each independently selected from an alkyl group and an aryl group with substituted or unsubstituted carbons.

Further, the solvent medium comprises at least one solvent having a boiling point greater than 100° C.; and at least one solvents having a boiling point less than 100° C.

The present disclosure further provides a method for planarizing a semiconductor substrate, comprising applying a composition onto and within a plurality of channels in the semiconductor substrate and curing the composition to form a coating which at least partially fills the channels of the substrate. The composition comprises at least one polysiloxane resin, a solvent medium, and a crosslinker including a siloxane compound. Each of the at least one polysiloxane resin comprises the reaction product of one or more monomers of the following formulas:

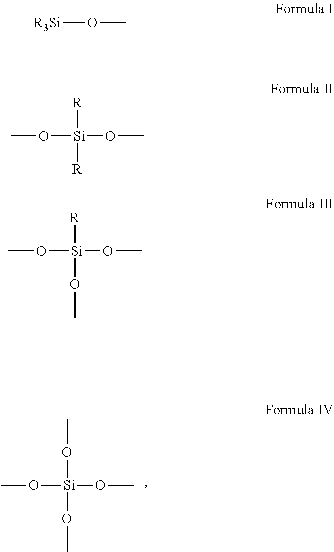

wherein R₁ and R₂ are each independently selected from an alkyl group and an aryl group with substituted or unsubstituted carbons.

Further, the solvent medium comprises at least one solvent having a boiling point greater than 100° C.; and at least one solvents having a boiling point less than 100° C.

### BRIEF DESCRIPTION OF THE DRAWINGS

The above-mentioned and other features and advantages of this disclosure, and the manner of obtaining them, will become more apparent, and will be better understood by reference to the following description of the exemplary embodiments taken in conjunction with the accompanying drawings, wherein:

FIG. 1 illustrates a semiconductor device with a trench having a depth D and a width W;

FIG. 2 illustrates the semiconductor device of FIG. 1 coated with a composition of the present disclosure;

FIG. 3 illustrates the coated semiconductor device of FIG. 2 including a liner composition and an overcoat composition;

FIG. 4 illustrates a method of applying the curable composition onto a substrate; and

FIG. 5 illustrates a method of applying a liner, the curable composition, an overcoat, and combinations thereof onto a substrate.

Corresponding reference characters indicate corresponding parts throughout the several views. Although the drawings represent embodiments of various features and components according to the present disclosure, the drawings are not necessarily to scale and certain features may be exaggerated in order to better illustrate and explain the present disclosure. The exemplification set out herein illustrates an embodiment of the invention, and such an exemplification is not to be construed as limiting the scope of the invention in any manner.

### DETAILED DESCRIPTION

For the purposes of promoting an understanding of the principles of the present disclosure, reference is now made to the embodiments illustrated in the drawings, which are described below. The exemplary embodiments disclosed herein are not intended to be exhaustive or to limit the disclosure to the precise form disclosed in the following detailed description. Rather, these exemplary embodiments were chosen and described so that others skilled in the art may utilize their teachings.

### I. Coating Composition

The present disclosure provides a curable composition for planarizing a surface of a substrate, such as a semiconductor device, such as a microprocessor, a memory device, a display employing light emitting diodes, or other types of displays, to planarize the semiconductor device surface. The composition may be applied by spin-coating to form a planarizing film on the semiconductor device. The planarizing film formed from the curable composition of the present disclosure have been found to exhibit high crack resistance, resistance to delamination, as well as high thermal resistance, even when the coatings are applied in layers having a relatively high thickness as compared to known planarizing coatings.

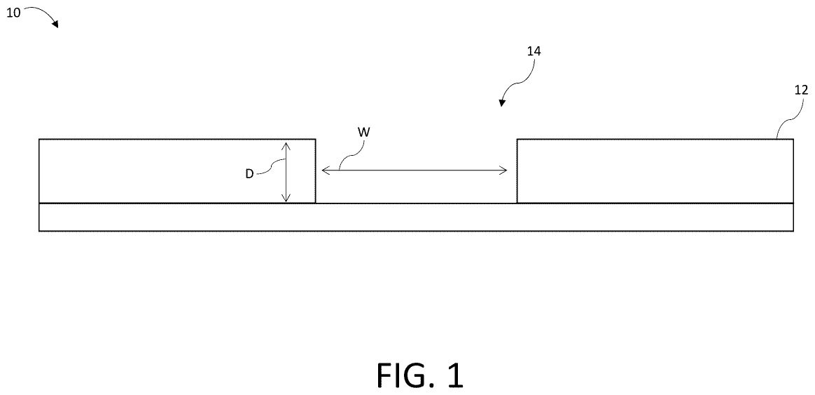

FIG. 1 is a schematic of a portion of a semiconductor device illustrating the surface to be planarized. Semiconductor 10 may include a substrate 12 and at least one surface feature 14, such as a trench. Trench 14 may have a width W of 0.1 μm, 1 μm, 10 μm, 20 μm, 30 μm, 40 μm, 50 μm to 60 μm, 80 μm, 100 μm, 200 μm, 500 μm, 1000 μm, 2000 μm, or any range including any two of the foregoing as end points, such as 0.1 μm to 2000 μm, 1 μm to 1000 μm, 10 μm to 500 μm, 20 μm to 200 μm, 30 μm to 100 μm, 40 μm to 80 μm, or 50 μm to 60 μm. Trench 14 may have a depth D of 0.1 μm, 1 μm, 5 μm, 10 μm, 15 μm to 20 μm, 25 μm, 30 μm, 100 μm, 500 μm, or any range including any two of the foregoing as end points, such as 0.1 μm to 500 μm, 1 μm to 100 μm, 5 μm to 30 μm, 10 μm to 25 μm, or 15 μm to 20 μm.

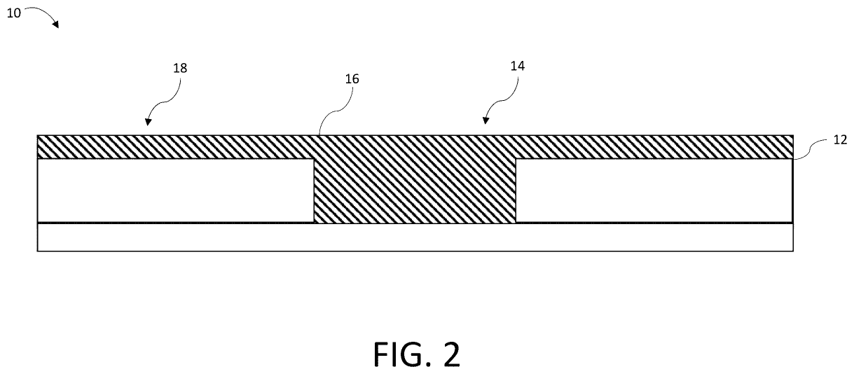

FIG. 2 illustrates semiconductor device 10 with a planarizing film formed from the cured composition of the present disclosure 16. The composition 16 may fill the trench 14 to provide a substantially planar surface 18 upon which subsequent devices layers may be formed (not shown). Cured composition 16 may have a thickness over a portion of the semiconductor device from 1 μm, 10 μm, 30 μm to 60 μm, 90 μm, 100 μm, or any range including any two of the foregoing as end points, such as 1 μm to 100 μm, 10 μm to 90 μm, or 30 μm to 60 μm.

FIGS. 1 and 2 illustrate one example in which a planarizing film may be formed. It is understood that the planarizing film formed from the cured composition 16 may be applied on many other topographies involving different arrangements of conductive, non-conductive, and semiconductive materials. For ease of illustration, one surface feature 14 is shown in FIGS. 1 and 2. However it is understood that semiconductor 10 can include a plurality of surface features 14.

The semiconductor device 10 may further be coated with a liner, an overcoat, or a combination thereof, as discussed below.

The planarizing film formed from cured composition 16 may be created by coating at least a portion of a semiconductor device 10 by spin-coating a curable composition. The curable composition may comprise at least one polysiloxane resin, a solvent medium, and a crosslinker. The composition may additionally comprise a catalyst.

### A. Polysiloxane Resin

The curable composition may comprise at least one polysiloxane resin. The polysiloxane resin can include polysilsesquioxane blocks and polydisiloxane blocks. The polysilsesquioxane blocks can include any type of polysilsesquioxane with the formula [RSiO3/2]n, wherein R is a hydrogen, an alkyl group, an aryl group, or an alkoxyl group. For example, the polysilsesquioxane blocks can include poly(methylsilsesquioxane) blocks, poly(phenylsilsesquioxane) blocks, poly(methylphenylsilsesquioxane), or any combinations thereof.

The polysiloxane resin may comprise the reaction product of one or more siloxane monomers of the following formulas:

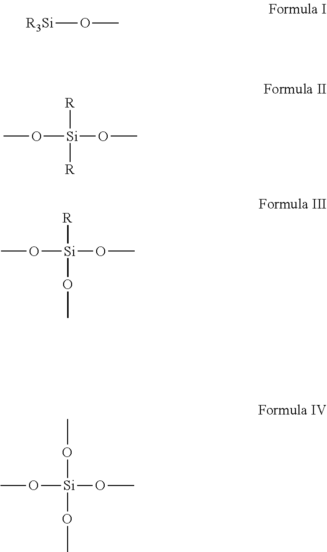

wherein R₁ and R₂ are each independently selected from an alkyl group and an aryl group with substituted or unsubstituted carbons.

The siloxane monomers may be described according to the degree of oxygen substitution, or functionality, on the central silicon atom.

TABLE 1
Siloxane Monomer Types

| Structural formula | Functionality | Symbol |
|---|---|---|
| 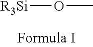 | Monofunctional | M |
| 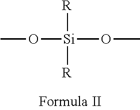 | Difunctional | D |
| 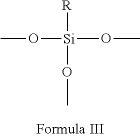 | Trifunctional | T |
| 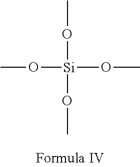 | Tetrafunctional | Q |

The polysiloxane resin may comprise the reaction product of monofunctional, difunctional, trifunctional, tetrafunctional siloxane monomers, or any combination thereof.

The polysiloxane resin may include at least one of a monofunctional siloxane monomer (Formula I) as end capping groups, such as triphenylsiloxane blocks, phenyldimethylsiloxane blocks, trimethylsiloxane blocks, or combinations thereof. The polysiloxane resin may include an amount of monofunctional siloxane blocks from 0.1 mol %, 1 mol %, 5 mol % to 10 mol %, 20 mol %, 30 mol %, or any range including any two of the foregoing values as end points, such as 0.1 to 30 mol %, 1 to 20 mol %, or 5 to 10 mol %, wherein mol % is based on the total moles of polysiloxane resin.

The polysiloxane resin may include at least one of a difunctional siloxane monomer (Formula II), such as poly(diphenylsiloxane) blocks, poly(phenylmethylsiloxane) blocks, poly(dimethylsiloxane) blocks, or combinations thereof. The polysiloxane resin may include an amount of difunctional siloxane blocks from 0.1 mol %, 1 mol %, 5 mol % to 10 mol %, 20 mol %, 30 mol %, or any range including any two of the foregoing values as end points, such as 0.1 to 30 mol %, 1 to 20 mol %, or 5 to 10 mol %, wherein mol % is based on the total moles of polysiloxane resin.

The polysiloxane resin may include at least one of a trifunctional siloxane monomer (Formula III), such as poly(methylsiloxane) blocks, poly(phenylsiloxane) blocks, poly(propylsiloxane) blocks, poly(ethylsiloxane) blocks, or combinations thereof. The polysiloxane resin may include an amount of trifunctional siloxane blocks from 0.1 mol %, 1 mol %, 5 mol % to 10 mol %, 20 mol %, 30 mol %, or any range including any two of the foregoing values as end points, such as 0.1 to 30 mol %, 1 to 20 mol %, or 5 to 10 mol %, wherein mol % is based on the total moles of polysiloxane resin.

The polysiloxane resin may include at least one of a tetrafunctional siloxane monomer (Formula IV), such as tetramethoxysilane, tetraethoxysilane, tetrachloride, silicon alkoxide, silicon tetraacetate, and combinations thereof. The polysiloxane resin may include an amount of tetrafunctional siloxane blocks from 0.1 mol %, 1 mol %, 5 mol % to 10 mol %, 20 mol %, 30 mol %, or any range including any two of the foregoing values as end points, such as 0.1 to 30 mol %, 1 to 20 mol %, or 5 to 10 mol %, wherein mol % is based on the total moles of polysiloxane resin.

The polysiloxane resin formed from siloxane monomers may further comprise end groups. Suitable end group may include hydroxysilane, chlorosilane, alkoxysilane, acryloxysilane, epoxysilane, and combinations thereof. These end groups may be further polymerizable. Suitable end groups may further include a non-reactive or chain terminating group, such as trialkylsilane.

The curable composition may comprise an amount of polysiloxane resin in an amount from 1 wt. %, 15 wt. %, 30 wt. % to 45 wt. %, 60 wt. %, 90 wt. %, or any range including any two of the foregoing values as end points, such as 1 wt. % to 90 wt. %, 15 wt. % to 60 wt. %, or 30 wt. % to 45 wt. %, wherein wt. % is based on the total weight of the curable composition.

### B. Solvent Medium

The curable composition may include a solvent medium. The solvent medium may comprise at least one high boiling point solvent and at least one low boiling point solvent. The solvent medium may comprise one or more high boiling point solvents and one or more low boiling point solvents. The solvent medium may specifically comprise two different low boiling point solvents.

Suitable high boiling point solvents may have a boiling point of at least 100° C., at least 120° C., at least 140° C., at least 160° C., at least 180° C., or within any range defined between any two of the foregoing values. High boiling point solvents may include glycol ethers such as dipropylene glycol methyl ether (DPM), tripropylene glycol methyl ether (TPM), propylene glycol monomethyl ether acetate (PGMEA), n-propoxypropanol (NPP), propylene carbonate, gammabutyro lactone, ethyl lactate, propylene glycol propyl ether (PGPE), propylene glycol methyl ether (PGME), propylene carbonate, ethyl lactate, isobutylacetate, indole-3-acetic acid (IAA), or combinations thereof.

Suitable low boiling point solvents may have a boiling point less than 100° C., less than 90° C., less than 80° C., less than 60° C., or within any range defined between any two of the foregoing values. Low boiling point solvents may include water, acetone, ethyl esters such as ethyl acetate, and lower molecular weight alcohols such as methanol, ethanol, propanol, isopropyl alcohol (IPA), methyl acetate, butanol, or any combination thereof.

The curable composition may comprise an amount of solvent medium from 10 wt. %, 15 wt. %, 30 wt. % to 60 wt. %, 90 wt. %, 99 wt. %, or any range including any two of the foregoing values as end points, such as 10 wt. % to 99 wt. %, 15 wt. % to 90 wt. %, or 30 wt. % to 60 wt. %, wherein wt. % is based on the total weight of the curable composition.

### C. Crosslinker

The curable composition may include a crosslinker. The crosslinker includes a siloxane compound according to the general Formula V:

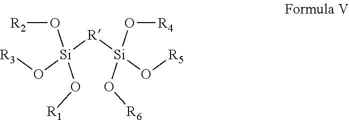

wherein R′ is one of an aliphatic and an aromatic comprising group and R₁, R₂, R₃, R₄, R₅, and R₆ are each independently selected from the group consisting of: H or an alkyl group with substituted or unsubstituted carbons. R may be an aliphatic group.

Suitable crosslinkers may have one of the following formulas:

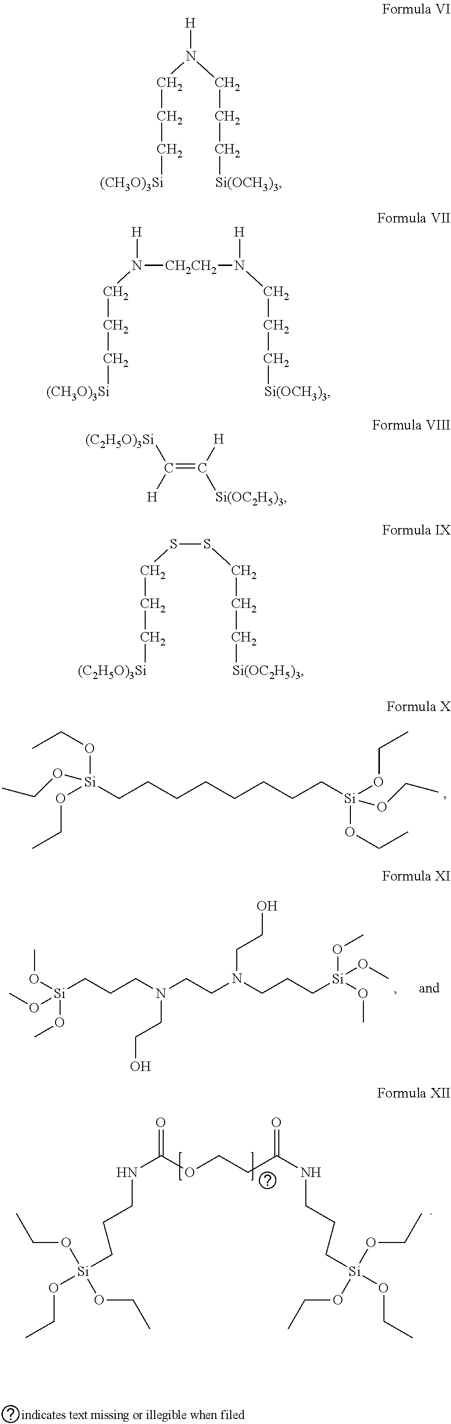

The crosslinker may be bis-(trimethoxysilylpropyl) amine (Formula VI), N, N′ bis(trimethoxysilylpropyl)ethylenediamine, (Formula VII), 1,2-bis(trimethoxysilyl) ethylene, (Formula VIII); bis[3-(triethoxysilyl)propyl]disulfide (Formula IX), bis-(triethoxysilylpropyl) amine, bis-(methyldimethoxysilylpropyl) amine, bis-(methyldiethoxysilylpropyl) amine, bis(trimethoxysilyl) methane, bis(triethoxysilyl) methane, 1,2-bis(triethoxysilyl) ethane, bis(trimethoxysilyl) benzene, bis(triethoxysilyl) benzene, or 1-(triethoxysilyl)-2-(diethoxymethylsilyl) ethane, 1,8-bis(triethoxysilyl)octane (Formula X), N,N′-bis(2-hydroxyethyl)-N,N′-bis(trimethoxysilylpropyl)ethylenediamine (Formula XI), N,N′-bis-[(3-triethoxysilylpropyl)aminocarbonyl]polyethylene oxide (Formula XII), or any combinations thereof. Such crosslinkers have high functionality to provide a greater chance of linking together high molecular weight chains, as well as low molecular weight oligomers.

Without wishing to be bound by any theories, it is believed that without crosslinkers as described above, high molecular weight chains cross-link directly, producing rigid structures that build up high stresses after high temperature exposure. It is further believed that insufficiently bonded low-molecular weight oligomers make the coatings weaker and more likely to crack due to the build-up of high stresses in the film. The high functionality crosslinkers bond together the high molecular weight chains at more locations to provide extra strength, while the aliphatic comprising group of the crosslinkers provides flexibility between the chains to reduce film stress. The high functionality crosslinkers also bond to more of the low-molecular weight oligomers, acting as chain extenders to increase the molecular weight of the film and increase the film strength. Thus, planarizing films may be able to resist cracking, even at thickness exceeding 6 microns and after exposure to temperatures exceeding 400° C.

The curable composition may comprise an amount of crosslinker from 0.0001 wt. %, 0.1 wt. %, 1 wt. % to 5 wt. %, 10 wt. %, 20 wt. %, or any range including any two of the foregoing values as end points, such as 0.0001 wt. % to 20 wt. %, 0.1 wt. % to 10 wt. %, or 1 wt. % to 5 wt. %, wherein wt. % is based on the total weight of the curable composition.

### D. Additives

The composition may include a one or more additives. Additives may include catalysts, surfactants, surface agents, filler, pigments, and wetting agents, and combinations thereof. The curable composition may comprise a total amount of additives from 0.1 wt. %, 0.5 wt. %, 1 wt. % to 5 wt. %, 10 wt. %, 20 wt. %, or any range including any two of the foregoing values as end points, such as 0.1 wt. % to 20 wt. %, 0.5 wt. % to 10 wt. %, or 1 wt. % to 5 wt. %, wherein wt. % is based on the total weight of the curable composition.

i. Catalysts

The curable composition may further comprise a catalyst. Catalysts may include tetraalkylammonium salts such as tetramethylammonium, tetrabutylammonium, cetyltrimethylammonium salts of acetic acid, triflic acid, trifluoro acetic acid, nitric acid, other organic and inorganic acids, and any combinations thereof. Such catalysts may be activated by heat after the composition is applied to the semiconductor device to cause polymerization and cross-linking of the curable composition to form the planarizing film.

Suitable catalysts may include, for example, tetramethylammonium acetate (TMAA), tetramethylammonium hydroxide (TMAH), tetrabutylammonium acetate (TBAA), cetyltrimethylammonium acetate (CTAA), tetramethylammonium nitrate (TMAN), triphenylamine, trioctylamine, tridodecylamine, triethanolamine, tetramethylphosphonium acetate, tetramethylphosphonium hydroxide, triphenylphosphine, trimethylphosphine, trioctylphosphine, aminopropyltriethoxysilane, aminopropyltriethoxysilane triflate, and any combinations thereof. Such catalysts can be activated by heat after the composition is applied to the semiconductor device to cause polymerization and cross-linking of the curable composition to form the planarizing film.

The curable composition may comprise an amount of catalyst from 0.0001 wt. %, 0.1 wt. %, 0.5 wt. % to 1 wt. %, 5 wt. %, 10 wt. %, or any range including any two of the foregoing values as end points, such as 0.0001 wt. % to 10 wt. %, 0.1 wt. % to 5 wt. %, or 0.5 wt. % to 1 wt. %, wherein wt. % is based on the total weight of the curable composition.

ii. Surfactant

It has been found that a surfactant can further reduce striations, which may be particularly useful when the composition is spin-coated onto larger diameter semiconductor device wafers or display substrates. The surfactant can be a polyether-modified polydimethylsiloxane surfactant, such a BYK®-306, BYK®-222, or BYK®-307 available from BYK-Chemie, Wesel, Germany; Novec™ Fluorosurfactant FC-4430 provided by 3M; and Tego® Flow 300 provided by Evonik Industries AG.

The curable composition may comprise an amount of surfactant from 0.0001 wt. %, 0.1 wt. %, 0.5 wt. % to 1 wt. %, 5 wt. %, 10 wt. %, or any range including any two of the foregoing values as end points, such as 0.0001 wt. % to 10 wt. %, 0.1 wt. % to 5 wt. %, or 0.5 wt. % to 1 wt. %, wherein wt. % is based on the total weight of the curable composition.

### II. Method of Application and Curing of the Composition

A method of planarizing a substrate may comprise applying the curable composition onto and within a plurality of surface features, such as trenches or channels, in a substrate, such as a semiconductor device; and curing the curable composition to form a coating or planarizing film which at least partially fills the channels of the substrate. The curable composition may be applied to the substrate using spin-coating or squeegee coating.

### A. Spin-Coating

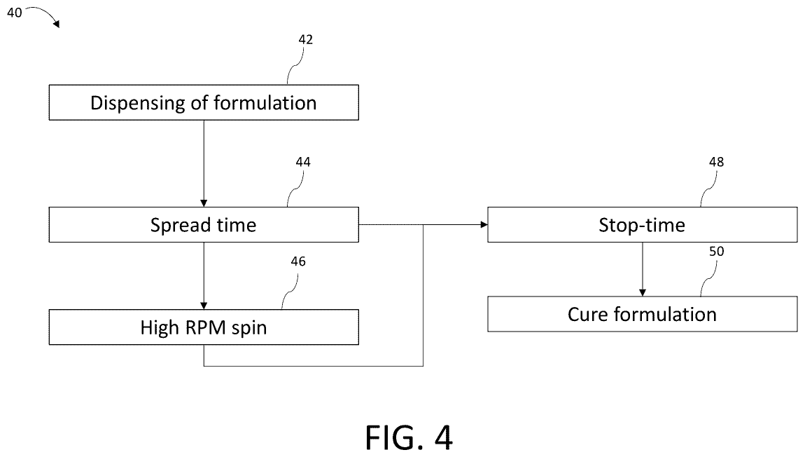

Spin coating methods may be employed to apply the coating onto a surface of the substrate, or “wafer,” to achieve a desired thickness of the coating. As shown in FIG. 4, method 40 includes a multi-step spin coating process. At block 42, the formulation may be dynamically or statically dispensed onto the wafer. The wafer may be loaded onto a spin plate and a coating solution of the planarizing composition is applied onto the center of the wafer. The curable composition may then be applied to the center of the wafer. After application, the wafer may be then spun to allow the composition to cover the surface of the wafer. In an alternate embodiment, the composition may be applied onto the surface of the wafer at a point away from the center of the wafer. The wafer may then be spun to achieve full coverage of the surface of the wafer.

Suitable application speeds may be from 100 revolutions per minute (rpm), 150 rmp, 200 rpm to 300 rpm, 400 rpm 500 rpm, or any range including any two of the foregoing values as end points, such as 100 rpm to 500 rpm, 150 rpm to 400 rpm, or 200 rpm to 300 rpm. Suitable spin times may be from 2 seconds (sec), 20 sec, 30 sec to 40 sec, 50 sec, 60 sec, or any range including any two of the foregoing values as end points, such as 1 sec to 60 sec, 20 sec to 50 sec, or 30 sec to 40 sec.

At block 44, the multi-step spin coating process then includes a spread-time during which the wafer is rotated without application of additional liquid formulation at a desired speed, and during which low boiling point solvents evaporate. Spread time may allow the composition to flow and achieve a planar surface along the surface. Suitable spread speeds may be from 0 rpm, 100 rpm, 200 rpm to 300 rpm, 400 rpm, 500 rpm, or any range including any two of the foregoing values as end points, such as 0 rpm to 500 rpm, 100 rpm to 400 rpm, or 200 rpm to 300 rpm. Suitable spread times may be from 0 sec, 20 sec, 30 sec to 40 sec, 50 sec, 60 sec, or any range including any two of the foregoing values as end points, such as 0 sec to 60 sec, 20 sec to 50 sec, or 30 sec to 40 sec.

The period of time between dispensing the composition onto the wafer and completing the spread-time of block 44 may constitute an evaporation time for the coating. The evaporation block 44, may comprise baking the coated wafer at a series of temperatures to evaporate the solvents. The wafer is baked at three different temperatures for three evaporation times. Suitable evaporation temperatures may be from 60° C., 80° C., 100° C. to 140° C., 180° C., 200° C., or any range including any two of the foregoing values as end points, such as 60° C. to 200° C., 80° C. to 180° C., or 100° C. to 140° C. The evaporation time may be from 0 sec, 40 sec, 60 sec to 80 sec, 100 sec, 120 sec, or any range including any two of the foregoing values as end points, such as 0 sec to 120 sec, 40 sec to 100 sec, or 60 sec to 80 sec.

After the evaporation time has elapsed, the composition may have a thickness greater than 1000 Angstroms (A), greater than 5000 A, greater than 10,000 A, greater than 20,000 A, greater than 30,000 A, greater than 50,000 A, greater than 80,000 A, greater than 100,000 A, greater than 500,000 A, greater than 1,000,000 A or within any range defined between any two of the foregoing values, wherein the thickness is measured using an ellipsometer or simplified evaporation method (SEM).

The multi-step spin coating process may include a high rpm spin at block 46, during which the wafer is rotated without application of additional liquid formulation to establish a desired film thickness. If the spin coating process does not include the high rpm spin, the method may proceed from block 44 to block 48.

Suitable high rpm speeds may be from 200 rpm, 500 rpm, 1000 rpm to 1500 rpm, 2000 rpm, 3000 rpm, or any range including any two of the foregoing values as end points, such as 200 rpm to 3000 rpm, 500 rpm to 2000 rpm, or 1000 rpm to 1500 rpm. Suitable high rpm spin times may be from 2 sec, 20 sec, 30 sec to 40 sec, 50 sec, 60 sec, or any range including any two of the foregoing values as end points, such as 1 sec to 60 sec, 20 sec to 50 sec, or 30 sec to 40 sec.

At block 48, the multi-step spin coating process may undergo a stop-time to facilitate flow of viscous fluid of a high boiling point solvent along the applied surface of the substrate. Suitable time periods for the stop-time may be from 2 sec, 20 sec, 30 sec to 40 sec, 50 sec, 60 sec, or any range including any two of the foregoing values as end points, such as 1 sec to 60 sec, 20 sec to 50 sec, or 30 sec to 40 sec.

### B. Curing

Once the curable composition is applied to the surface of the substrate, the composition may be cured to create the planarizing film. Still referencing the method of FIG. 4, at block 49, the composition may be cured onto the applied surface. Suitable temperatures for curing may be from 160° C., 190° C., 200° C. to 250° C., 300° C., 400° C., or any range including any two of the foregoing values as end points, such as 160° C. to 400° C., 190° C. to 300° C., or 200° C. to 250° C. The curable composition may be cured at a previously mentioned temperature for 30 sec, 1 minute (min), 30 min, 40 min to 60 min, 90 min, 180 min, 360 min, or within any range defined between any two of the foregoing values, such as 30 sec to 360 min, 1 min to 180 min, 30 min to 90 min, or 40 min to 60 min.

### C. Liner

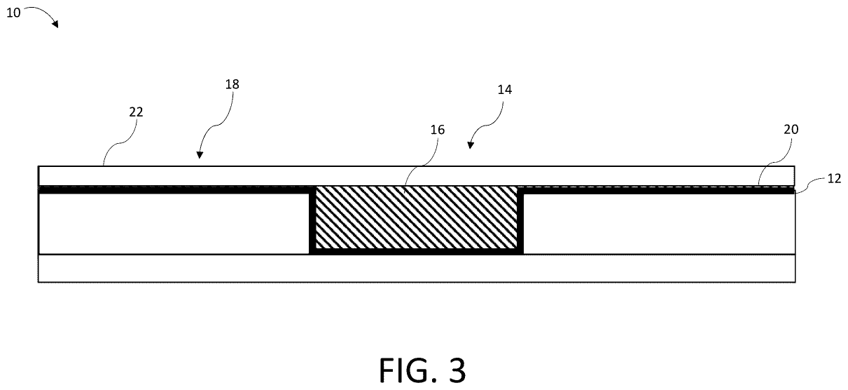

The method of applying the curable composition may include applying a liner to the surface of the substrate before applying the curable composition 16. As seen in FIG. 3, a liner layer 20 may be applied to surface 12 of semiconductor 10. The liner may be SiN, SiOₓ, a polysiloxane coating, or any other spin on glass coating, such as Honeywell polysiloxane coating product T41C.

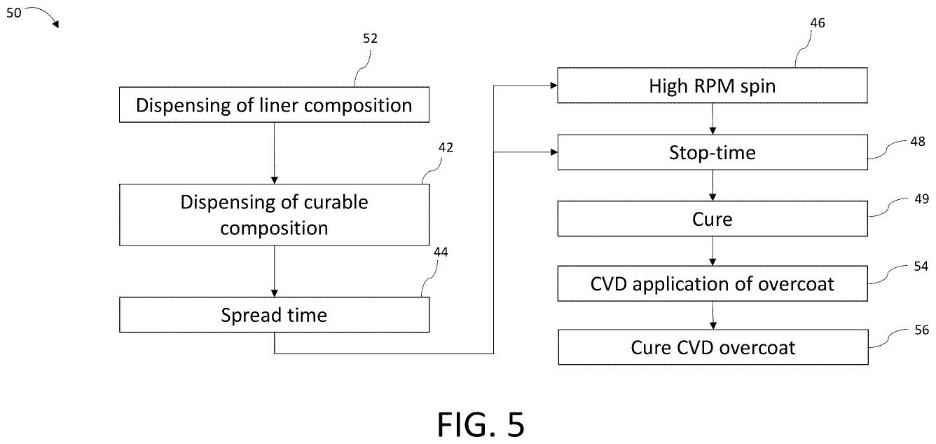

The liner may be applied via the spin-coating process as described above in reference to the application of the curable composition. Referencing method 50 in FIG. 5, the liner may be applied to the wafer before application of the curable composition in block 52. The liner may be applied statically or dynamically using spin coating. Blocks 42-49 in FIG. 5 include the same steps as described above in reference to method 40 in FIG. 4. Following the application process, the liner may be optionally cured or baked before coating the substrate with the curable composition.

Once applied and cured, the liner may have a thickness of 10 A, 20 A, 40 A, 45 A, 50 A, 55 A to 60 A, 65 A, 100 A, 200 A, 500 A, 1000 A, or within any range defined between any two of the foregoing values, such as 10 A to 1000 A, 20 A to 500 A, 40 A to 200 A, 45 A to 100 A, 50 A to 65 A, or 55 A to 60 A, wherein the thickness is measured using an ellipsometer.

In addition to the liner, which serves as an adhesion promoter, a surface treatment coated onto the substrate to improve the adhesion between the substrate and the coatings. Suitable surface treatments may include a plasma treatment.

### D. Overcoat

The method of applying the curable composition may further include applying an overcoat after the curable composition is cured to form the planarizing film. As seen in FIG. 3, an overcoat layer 22 may be applied on top of cured composition 16 within surface feature 14 of semiconductor 10. The overcoat may comprise a dielectric material, such as a nanoporous silica film. Suitable overcoat compositions may include silicon dioxide (SiO₂), silicon nitride (SiN), silicon oxynitride (SiOₓN_{y}), polysiloxane, or other spin on glass coatings.

The overcoat may be applied on top of the planarizing film by spin coating, dip coating, spray coating, or chemical vapor deposition (CVD). Referencing method 50 in FIG. 5, after the curable composition is cured, the overcoat may be applied on top of the curable composition in block 54. The overcoat may then be cured in block 56.

The overcoat may be applied such that it has a thickness from 0.1 μm, 0.5 μm, 1 μm, 1.5 μm to 2 μm, 2.5 μm, 3 μm, 5 μm, or within any range defined between any two of the foregoing values, such as 0.1 μm to 5 μm, 0.5 μm to 3 μm, 1 μm to 2.5 μm, or 1.5 μm to 2 μm.

The overcoat may be cured to create an overcoat film. Suitable curing temperature to form the overcoat film may be from 160° C., 190° C., 200° C. to 250° C., 300° C., 400° C., or any range including any two of the foregoing values as end points, such as 160° C. to 400° C., 190° C. to 300° C., or 200° C. to 250° C. The overcoat may be cured at a previously mentioned temperature for 1 min, 10 min, 20 min to 25 min, 30 min, 40 min, or within any range defined between any two of the foregoing values, such as 1 min to 40 min, 10 min to 30 min, or 20 min to 25 min.

### EXAMPLES

Aspects of the present disclosure are further illustrated by reference to the following examples. It will be apparent to those skilled in the art that many modifications, both to materials, and methods, may be practiced without departing from the scope of the disclosure.

### Comparative Examples

### Comparative Composition 1

In a 250 ml flask, 45.0 g of GR950F resin was added to 55.0 g of PGMEA and stirred overnight at room temperature to form a 45% GR950F resin solution. To the 250 ml flask, 1.25 g of the 10 wt. % BYK-307 surfactant solution prepared in ethanol, 0.8 g of the tetramethylammonium nitrate (TMAN) solution prepared in deionized water were added to the 100 g of the GR950F resin solution and stirred for 3 hours at room temperature to form a planarizing composition.

The planarizing composition was filtered through a 0.1 micron filter. The filtered planarizing composition was coated on a four-inch silicon wafer by spin coating at 1,000 RPM.

The wafer with the cast film was baked on a series of three hot plates in air ambient for 60/60/120 seconds respectively: a first hot plate having a surface temperature of 80° C., a second hot plate having a surface temperature of 160° C., and a third hot plate having a surface temperature of 180° C. to evaporate the solvents. The film thickness was measured at 41430 A on ellipsometer. The wafer with the baked coating was cured in nitrogen ambient in a furnace at 300° C. for 30 minutes.

Uniform coating was not obtained when coated the solution at spin speed of 600 rpm by using a standard spin coating process.

The solution was spin coated at 1000 rpm on wafer coupons with 20 μm deep 80 μm wide trench patterns.

The coupon was baked at the same conditions as those used for 4-inch wafers, followed by curing on a hot plate at 250° C. for 5 min.

Cross-section of the patterns were inspected under SEM, which showed the trench fill was incomplete, severe film cracking was observed in the film.

### Comparative Composition 2

In a 250 ml flask, 45.0 g of SST-3PM4 resin was added to 55.0 g of PGMEA and stirred overnight at room temperature to form a 45% SST-3PM4 resin solution. In another 250 ml flask, 45.0 g of SST-3PM2 resin was added to 55.0 g of PGMEA and stirred overnight at room temperature to form a 45% SST-3PM2 resin solution. In another 250 ml flask, 1.25 g of the 10 wt. % BYK-307 surfactant solution prepared in ethanol, 0.8 g of the tetramethylammonium nitrate (TMAN) solution prepared in deionized water, 0.225 g trifluoroacetic acid, and 0.45 g of (bis-(trimethoxysilylpropyl) amine were added to 100 g of the SST-3PM4 resin solution and 1 g of the SST-3PM2 resin solution and stirred for 3 hours at room temperature to form a planarizing composition.

The planarizing composition was filtered through a 0.1 micron filter. The filtered planarizing composition was coated on a four-inch silicon wafer by spin coating at 1,000 RPM.

The wafer with the cast film was baked on a series of three hot plates in air ambient for 60/60/120 seconds respectively: a first hot plate having a surface temperature of 80° C., a second hot plate having a surface temperature of 160° C., and a third hot plate having a surface temperature of 180° C. to evaporate the solvents. The film thickness was measured at 43354 A on ellipsometer. The wafer with the baked coating was cured in nitrogen ambient in a furnace at 300° C. for 30 minutes.

Uniform coating was not obtained when coated the solution at spin speed of 600 rpm by using a standard spin coating process.

The solution was spin coated at 1000 rpm on wafer coupons with 20 μm deep 80 μm wide trench patterns.

The coupon was baked at the same conditions as those used for 4-inch wafers, followed by curing on a hot plate at 250° C. for 5 min.

Cross-section of the patterns were inspected under SEM, which showed the trenches fill was incomplete, there was no film cracking.

### Comparative Composition 3

In a 250 ml flask, 35.0 g of SST-3PM4 resin was added to 65.0 g of PGMEA and stirred overnight at room temperature to form a 35% SST-3PM4 resin solution. In another 250 ml flask, 35.0 g of SST-3PM2 resin was added to 35.0 g of PGMEA and stirred overnight at room temperature to form a 35% SST-3PM2 resin solution. In another 250 ml flask, 5 g of the 10 wt. % BYK-307 surfactant solution prepared as in ethanol, 0.8 g of the tetramethylammonium nitrate (TMAN) solution prepared in deionized water, 0.175 g trifluoroacetic acid, and 0.35 g of (bis-(trimethoxysilylpropyl) amine were added to 100 g of the SST-3PM4 resin solution and 1 g of the SST-3PM2 resin solution and stirred for 3 hours at room temperature to form a planarizing composition.

The planarizing composition was filtered through a 0.1 micron filter. The filtered planarizing composition was coated on a four-inch silicon wafer by spin coating at 1,000 RPM.

The wafer with the cast film was baked on a series of three hot plates in air ambient for 60/60/120 seconds respectively: a first hot plate having a surface temperature of 80° C., a second hot plate having a surface temperature of 160° C., and a third hot plate having a surface temperature of 180° C. to evaporate the solvents. The film thickness was measured at 30546 A on ellipsometer. The wafer with the baked coating was cured in a nitrogen ambient in a furnace at 300° C. for 30 minutes.

The solution was spin coated with double coating at 1000 rpm on wafer coupons with 20 μm deep 80 μm wide trench patterns.

The coupon was baked at the same conditions as those used for 4-inch wafers, followed by curing on a hot plate at 250° C. for 5 min.

Cross-section of the patterns were inspected under SEM, which showed the trenches fill was incomplete, film delamination was observed.

### Comparative Composition 4

PTSRE50C is a planarizing composition (comparative composition 4) obtained from Honeywell Electronic Materials, Santa Clara, California, which consists of polysiloxane resins including 50% wt % of GR150F and 50% wt % of GR950.

The planarizing composition was filtered through a 0.1 micron filter. The filtered planarizing composition was coated on a four-inch silicon wafer by spin coating at 1,000 RPM.

The wafer with the cast film was baked on a series of two hot plates in air ambient for 60/60 seconds respectively: a first hot plate having a surface temperature of 160° C., and a second hot plate having a surface temperature of 180° C. to evaporate the solvents.

The wafer received a second coating and a third coating, each spun at the same speed as for their first coating and baked again on the hot plates as described above

The film thickness was measured at 53929 A on ellipsometer. The wafer with the baked coating was cured in nitrogen ambient in a furnace at 360° C. for 30 minutes.

Film cracking were observed on wafer edges.

### Examples

### Inventive Composition 1

In a 250 ml flask, 33.0 g of SST-3PM4 resin was added to 33.5 g of PGMEA and 33.5 g of IPA, stirred overnight at room temperature to form a 33% SST-3PM4 resin solution. In another 250 ml flask, 33.0 g of SST-3PM2 resin was added to 67.0 g of PGMEA and stirred overnight at room temperature to form a 33% SST-3PM2 resin solution. In another 250 ml flask, 5 g of the 10 wt. % BYK-307 surfactant solution prepared as in ethanol, 0.8 g of the tetramethylammonium nitrate (TMAN) solution prepared in deionized water, 0.165 g trifluoroacetic acid, and 0.33 g of (bis-(trimethoxysilylpropyl) amine were added to 100 g of the SST-3PM4 resin solution and 1 g of the SST-3PM2 resin solution and stirred for 3 hours at room temperature to form a planarizing composition.

The planarizing composition was filtered through a 0.1 micron filter. The filtered planarizing composition was coated on a four-inch silicon wafer by spin coating at 1,000 RPM.

The wafer with the cast film was baked on a series of three hot plates in air ambient for 60/60/120 seconds respectively: a first hot plate having a surface temperature of 80° C., a second hot plate having a surface temperature of 160° C., and a third hot plate having a surface temperature of 180° C. to evaporate the solvents. The film thickness was measured at 31701 A on ellipsometer, striation was observed on the film.

The wafer with the baked coating was cured in a nitrogen ambient in a furnace at 300° C. for 30 minutes, film thickness is 30989 A after curing.

Low speed spreading process was investigated for this formulation by adding 300 rpm spinning step before main spin speed at 1000 rpm. The film thickness increased with the low rpm spreading time, from 31701 A for no spreading to 65639 A for 60 s′ spreading at 300 rpm before spinning at 1000 rpm for 20 seconds.

TABLE 1
Spin-Coating Process for Comparative Coating 4

| | | | Post-bake | Post-cure |
|---|---|---|---|---|
| | Bake | Cure | film | film |
| Spin process | temp | temp | thickness | thickness |
| 1000 rpm 20 sec | 160/180° C. | 300° C. | 31701 A | 30989 A |
| 300 rpm 10 sec, | 1 min | 30 min N² | 41390 A | 40491 A |
| 1000 rpm 20 sec | | | | |
| 300 rpm 20 sec, | | | 54419 A | 52468 A |
| 1000 rpm 20 sec | | | | |
| 300 rpm 30 sec, | | | 57258 A | 56083 A |
| 1000 rpm 20 sec | | | | |
| 300 rpm 60 sec, | | | 65639 A | 59142 A |
| 1000 rpm 20 sec | | | | |

The solution was spin coated with double coating at 1000 rpm on wafer coupons with 20 μm deep 80 μm wide trench patterns.

The coupon was baked at the same conditions as those used for 4-inch wafers, followed by curing on a hot plate at 250° C. for 5 min.

Cross-section of the patterns were inspected under SEM, which showed the trenches fill was incomplete, and some minor film delamination was observed.

Incomplete fill of the trenches/channels refers to the planarizing composition partially filling 20 μm deep trenches/channels because of lower film thickness but is otherwise not an indicator of heat/crack failure. The coating may fill a trench/channel of a lower depth.

Film delamination refers to when the stress is higher than the adhesion between the composition and the substrate. Delamination may be solved using lower stress compositions or reducing the process temperature, and minor delamination is not indicator of failure.

### Inventive Composition 2

In a 250 ml flask, 25.0 g of SST-3PM4 resin was added to 25.0 g of PGMEA, 25.0 g of acetone and 25.0 g of IPA, stirred overnight at room temperature to form a 25% SST-3PM4 resin solution. In another 250 ml flask, 25.0 g of SST-3PM2 resin was added to 75.0 g of PGMEA and stirred overnight at room temperature to form a 25% SST-3PM2 resin solution. In another 250 ml flask, 5 g of the 10 wt. % BYK-307 surfactant solution prepared as in ethanol, 0.8 g of the tetramethylammonium nitrate (TMAN) solution prepared in deionized water, 0.125 g trifluoroacetic acid, and 0.25 g of (bis-(trimethoxysilylpropyl) amine were added to 100 g of the SST-3PM4 resin solution and 1 g of the SST-3PM2 resin solution and stirred for 3 hours at room temperature to form a planarizing composition.

The planarizing composition was filtered through a 0.1 micron filter. The filtered planarizing composition was coated on a four-inch silicon wafer by spin coating at 1,000 rpm.

The wafer with the cast film was baked on a series of three hot plates in air ambient for 60/60/120 seconds respectively: a first hot plate having a surface temperature of 80° C., a second hot plate having a surface temperature of 160° C., and a third hot plate having a surface temperature of 180° C. to evaporate the solvents. The film thickness was measured at 20498 A on ellipsometer. The wafer with the baked coating was cured in a nitrogen ambient in a furnace at 300° C. for 30 minutes.

The solution was spin coated at 300 rpm for 10 seconds then 1000 rpm for 20 seconds on wafer coupons with 20 μm deep 80 μm wide trench patterns.

The coupon was baked at the same conditions as those used for 4-inch wafers, followed by curing on a hot plate at 250° C. for 5 min.

Cross-section of the patterns were inspected under SEM, which showed the trenches fill was incomplete. Incomplete fill of the trenches/channels refers to the planarizing composition partially filling 20 μm deep trenches/channels because of lower film thickness but is otherwise not an indicator of heat/crack failure. The coating may fill a trench/channel of a lower depth.

In another coupon coating, the solution was spin coated at 300 rpm with double coating, the coupon was baked at the same conditions as those used for 4-inch wafers to evaporate the solvents. The coupon with the baked coating was cured in a nitrogen ambient in a furnace at 300° C. for 30 minutes.

Cross-section of the patterns were inspected under SEM, which showed the trenches were completely filled, minor delamination was observed between film and trench wall.

### Inventive Composition 3

In a 250 ml flask, 30.0 g of SST-3PM4 resin was added to 23.3 g of PGMEA, 23.3 g of acetone and 23.3 g of IPA, stirred overnight at room temperature to form a 30% SST-3PM4 resin solution. In another 250 ml flask, 30.0 g of SST-3PM2 resin was added to 70.0 g of PGMEA and stirred overnight at room temperature to form a 30% SST-3PM2 resin solution. In another 250 ml flask, 5 g of the 10 wt. % BYK-307 surfactant solution prepared as in ethanol, 0.8 g of the tetramethylammonium nitrate (TMAN) solution prepared in deionized water, 0.125 g trifluoroacetic acid, and 0.25 g of (bis-(trimethoxysilylpropyl) amine were added to 100 g of the SST-3PM4 resin solution and 1 g of the SST-3PM2 resin solution and stirred for 3 hours at room temperature to form a planarizing composition.

The planarizing composition was filtered through a 0.1 micron filter. The filtered planarizing composition was coated on a four-inch silicon wafer by spin coating at 1,000 RPM.

The wafer with the cast film was baked on a series of three hot plates in air ambient for 60/60/120 seconds respectively: a first hot plate having a surface temperature of 80° C., a second hot plate having a surface temperature of 160° C., and a third hot plate having a surface temperature of 180° C. to evaporate the solvents. The film thickness was measured at 38966 A on ellipsometer. The wafer with the baked coating was cured in a nitrogen ambient in a furnace at 300° C. for 30 minutes.

The solution was spin coated at 300 rpm for 10 seconds then 1000 rpm for 20 seconds on wafer coupons with 20 μm deep 80 μm wide trench patterns. The coupon was baked at the same conditions as those used for 4-inch wafers, followed by curing in a nitrogen ambient in a furnace at 300° C. for 30 minutes.

Cross-section of the patterns were inspected under SEM, which showed the trenches were completely filled, minor delamination was observed between film and trench wall.

### Inventive Composition 4

In a 100 ml flask, 12.5 g of SST-3PM4 and 0.125 g SST-3PM2 were added to 12.5 g of PGMEA, 12.5 g of acetone and 9.13 g of IPA, stirred overnight at room temperature to form a clear solution. 2.5 g of the 10 wt. % BYK-307 surfactant solution prepared as in ethanol, 0.16 g of the tetramethylammonium nitrate (TMAN) solution prepared in deionized water, 1.25 g 10% trifluoroacetic acid prepared in IPA, and 2.5 g of 10% (bis-(trimethoxysilylpropyl) amine prepared in IPA, and 1.01 g methyltriacetoxysilane were added to the solution as end capping agent for the polymers, the solution was stirred for 3 hours at room temperature to form a planarizing composition.

The planarizing composition was filtered through a 0.1 micron filter.

The solution was spin coated at 300 rpm for 30 seconds on wafer coupons with 20 μm deep 80 μm wide trench patterns.

The coupon was baked at 80 for 1 min on the first hot plate, 130° C. for 1 min on the 2nd hot plate, and 180° C. for 2 min on the third hot plate, followed by curing at 300° C. for 30 min in furnace.

Cross-section of the patterns were inspected under SEM, which showed the trenches were completely filled with no cracking.

### Inventive Composition 5

In another example, the solution prepared in inventive composition 1 was coated on 8 inch blanket wafers by using squeegee coating. The wafers with the cast film were baked on a series of three hot plates in air ambient for 60/60/120 seconds respectively: a first hot plate having a surface temperature of 80° C., a second hot plate having a surface temperature of 160° C., and a third hot plate having a surface temperature of 180° C. to evaporate the solvents. A film thickness less than 10 μm was obtained.

The wafers with the baked coating were cured in a nitrogen ambient in a furnace at 300° C. for 30 minutes. On one of the cured wafers, a layer of 2 μm CVD SiO2 was deposited by using P5000, a CVD SiOx deposition tool supplied by Applied Materials.

The wafer was put in the furnace to repeat the 300° C. 30 min curing process for ten times, wafers with same polymer coatings but no CVD SiO were cured in the same process for comparison.

After the 10 thermal curing cycles the CVD coated wafer was inspected by SEM, no crack was observed. As comparison, the other wafer without CVD SiO showed severe film cracking. As shown by the thermal curing cycles, the wafer coated with the planarizing composition and CVD is more resistant to cracking than the wafer without CVD.

### Inventive Composition 6

In another example, Honeywell polysiloxane coating product T41C was diluted and spin coated on a coupon with 20 μm deep 80 μm wide trench patterns to form a 53 A thick liner coating. Then, the spin coating solution prepared in inventive composition 1 was spin coated with double coating at 300 rpm for 10 seconds then 1000 rpm for 20 seconds on wafer coupons with 20 μm deep 80 μm wide trench patterns.

The coupon was baked at the same conditions as those used for 4-inch wafers, followed by curing in a nitrogen ambient in a furnace at 300° C. for 30 minutes.

Cross-section of the patterns were inspected under SEM, which showed the trenches were completely filled with no delamination.

Wherein particular examples of this invention have been described above for purposes of illustration, it will be evident to those skilled in the art that numerous variations of the details of the present invention may be made without departing from the invention as defined in the appended claims. This application is therefore intended to cover any variations, uses, or adaptations of the disclosure using its general principles. Further, this application is intended to cover such departures from the present disclosure as come within known or customary practice in the art to which this disclosure pertains and which fall within the limits of the appended claims.

### Inventive Composition 7

In a 100 ml flask, 0.06 g of 1,4-Bis-triethoxysilyl benzene was added to 30 g PTSRE50C and stirred for 1 hour at room temperature to form a planarizing composition. The planarizing composition was filtered through a 0.1 micron filter.

The filtered planarizing composition was coated on three four-inch silicon wafer by spin coating at 1,300 RPM.

The wafers with the cast film were baked on a series of two hot plates in air ambient for 60/60 seconds respectively: a first hot plate having a surface temperature of 160° C., and a second hot plate having a surface temperature of 180° C. to evaporate the solvents.

Each of the three wafers received a second coating and hot plate baking as described above. Two of the three wafers each received a third coating and hot plate baking as described above. One of the two wafers with three coatings received a fourth coating and hot plate baking as described above.

A thickness of baked coating was measured for each of the wafers and found to be 29587 A for the double coating, 44823 A for the triple coating, and 61150 A for the quadruple coating.

The wafers with the baked coating were cured in nitrogen ambient in a furnace at 410° C. for 30 minutes.

No film cracking were observed on the three wafers with double, triple or quadruple coating.

### Inventive Composition 8

In a 100 ml flask, 0.12 g of 1,4-Bis-triethoxysilyl benzene was added to 30 g PTSRE50C and stirred for 1 hour at room temperature to form a planarizing composition. The planarizing composition was filtered through a 0.1 micron filter. The filtered planarizing composition was coated on three four-inch silicon wafer by spin coating at 1,300 RPM.

The wafers with the cast film were baked on a series of two hot plates in air ambient for 60/60 seconds respectively: a first hot plate having a surface temperature of 160° C., and a second hot plate having a surface temperature of 180° C. to evaporate the solvents.

Each of the three wafers received a second coating and hot plate baking as described above. Two of the three wafers each received a third coating and hot plate baking as described above. One of the two wafers with three coatings received a fourth coating and hot plate baking as described above.

A thickness of baked coating was measured for each of the wafers and found to be 29556 A for the double coating, 45525 A for the triple coating, and 63529 A for the quadruple coating.

The wafers with the baked coating were cured in nitrogen ambient in a furnace at 410° C. for 30 minutes.

No film cracking were observed on the three wafers with double, triple or quadruple coating.

### Inventive Composition 9

In a 100 ml flask, 0.30 g of 1,4-Bis-triethoxysilyl benzene was added to 30 g PTSRE50C and stirred for 1 hour at room temperature to form a planarizing composition. The planarizing composition was filtered through a 0.1 micron filter. The filtered planarizing composition was coated on three four-inch silicon wafer by spin coating at 1,300 RPM.

The wafers with the cast film were baked on a series of two hot plates in air ambient for 60/60 seconds respectively: a first hot plate having a surface temperature of 160° C., and a second hot plate having a surface temperature of 180° C. to evaporate the solvents.

Each of the three wafers received a second coating and hot plate baking as described above. Two of the three wafers each received a third coating and hot plate baking as described above. One of the two wafers with three coatings received a fourth coating and hot plate baking as described above.

A thickness of baked coating was measured for each of the wafers and found to be 29288 A for the double coating, 45159 A for the triple coating, and 60922 A for the quadruple coating.

The wafers with the baked coating were cured in nitrogen ambient in a furnace at 410° C. for 30 minutes.

No film cracking were observed on the three wafers with double, triple or quadruple coating.

Wherein particular examples of this invention have been described above for purposes of illustration, it will be evident to those skilled in the art that numerous variations of the details of the present invention may be made without departing from the invention as defined in the appended claims. This application is therefore intended to cover any variations, uses, or adaptations of the disclosure using its general principles. Further, this application is intended to cover such departures from the present disclosure as come within known or customary practice in the art to which this disclosure pertains and which fall within the limits of the appended claims.

What is claimed is:

1. A composition for planarizing a substrate, comprising:
a polysiloxane resin comprising the reaction product of one or more monomers of the following formulas: 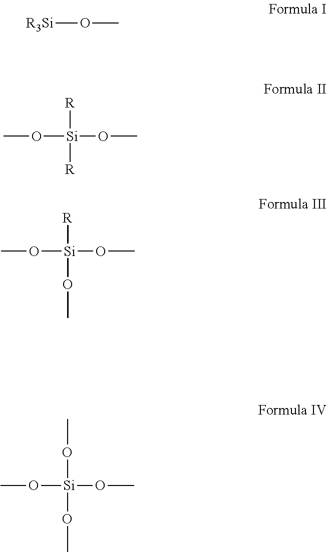
wherein R is independently selected from an unsubstituted or substituted alkyl group and an unsubstituted or substituted aryl group;
a solvent medium, comprising:
at least one solvent having a boiling point greater than 100° C.; and
at least one solvent having a boiling point less than 100° C.; and
a crosslinker.

2. The composition of claim 1, wherein the monomer of Formula I comprises at least one of:
triphenylsiloxane blocks;
phenyldimethylsiloxane blocks; and
trimethylsiloxane blocks;
the monomer of Formula II comprises at least one of:
poly(diphenylsiloxane) blocks;
poly(phenylmethylsiloxane) blocks; and
poly(dimethylsiloxane) blocks;
the monomer of Formula III comprises at least one of:
poly(methylsiloxane) blocks;
poly(phenylsiloxane) blocks;
poly(propylsiloxane) blocks; and
poly(ethylsiloxane) blocks; and
the monomer of Formula IV comprises at least one of:
tetramethoxysilane;
tetraethoxysilane;
silicon tetrachloride;
silicon alkoxide; and
silicon tetraacetate.

3. The composition of claim 1, wherein the crosslinker is a siloxane compound of the general formula: 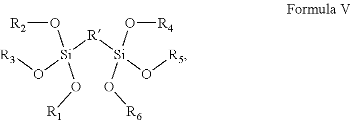
wherein R′ is one of an aliphatic and an aromatic comprising group and R₁, R₂, R₃, R₄, R₅, and R₅ are each independently selected from hydrogen and an alkyl group with substituted or unsubstituted carbons.

4. The composition of claim 1, wherein the crosslinker is selected from the following formulas: 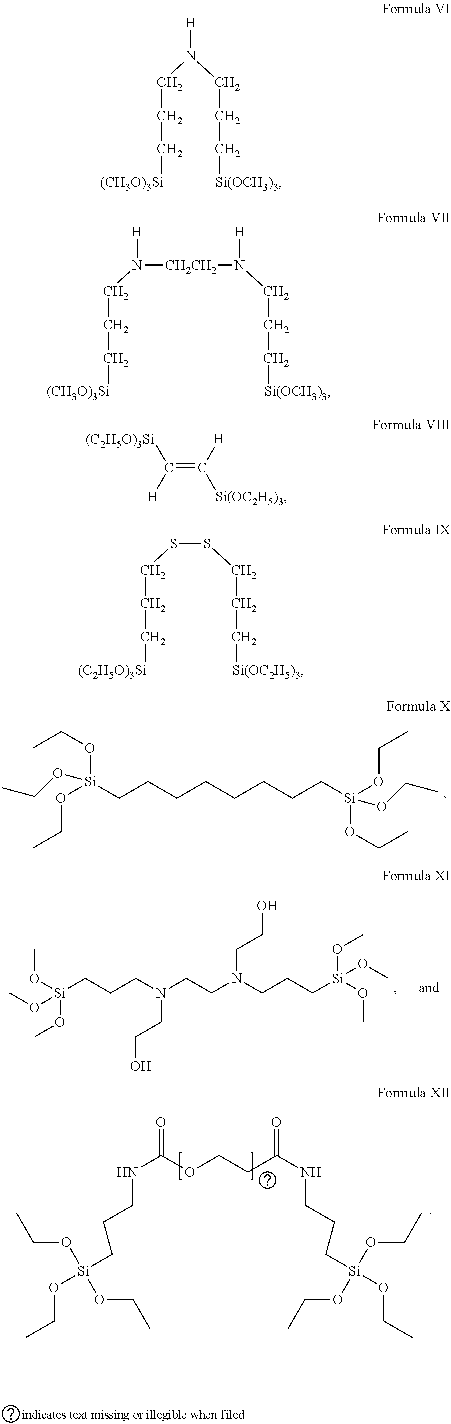
and combinations of the foregoing.

5. The composition of claim 1, further comprising a catalyst, wherein the catalyst is selected from tetraalkylammonium salts such as tetramethylammonium, tetrabutylammonium, cetyltrimethylammonium salts of acetic acid, triflic acid, trifluoro acetic acid, nitric acid, and combinations of the foregoing.

6. The composition of claim 5, wherein the composition comprises:
from 1 to 90 wt. % of polysiloxane resin;
from 0.0001 to 10 wt. % of the catalyst;
from 10 to 99 wt. % of the at least one solvent; and
from 0.0001 to 20 wt. % of the crosslinker, each based on a total weight of the composition.

7. The composition of claim 1, wherein the at least one solvent having a boiling point greater than 100° C. is selected from dipropylene glycol methyl ether, tripropylene glycol methyl ether, propylene glycol monomethyl ether acetate, n-propoxypropanol, and propylene carbonate, gammabutryo lactone, and combinations of the foregoing.

8. The composition of claim 1, wherein the at least one solvent having a boiling point less than 100° C. comprises at least two different solvents.

9. The composition of claim 8, wherein each of the two different solvents having a boiling point less than 100° C. are independently selected from acetone, ethyl acetate, methanol, ethanol, propanol, butanol, and isopropyl alcohol.

10. The composition of claim 1, wherein the polysiloxane resin further comprises end groups derived from hydroxysilane, chlorosilane, alkoxysilane, acryloxysilane, epoxysilane, non-reactive or chain terminating end groups, and combinations of the foregoing;

11. A semiconductor article coated with a cured composition of claim 1.

12. A method for planarizing a semiconductor substrate, comprising:
applying a composition onto and within a plurality of channels in the semiconductor substrate, the composition comprising:
a polysiloxane resin comprising the reaction product of one or more monomers of the following formulas: 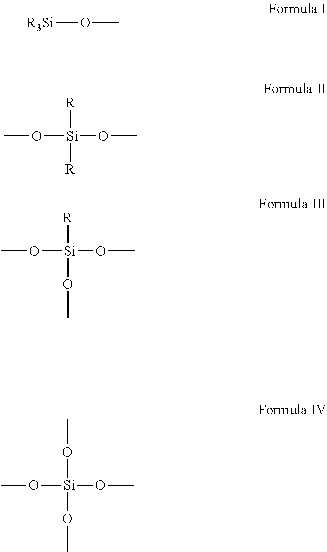
wherein R is independently selected from an unsubstituted or substituted alkyl group and an unsubstituted or substituted aryl group;
a solvent medium, comprising:
at least one solvent having a boiling point greater than 100° C.; and
at least one solvent having a boiling point less than 100° C.; and
a crosslinker; and
curing the composition to form a coating which at least partially fills the channels of the substrate.

13. The method of claim 12, wherein the crosslinker is a siloxane compound of the general formula: 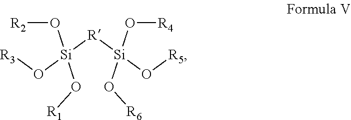
wherein R′ is one of an aliphatic and an aromatic comprising group and R₁, R₂, R₃, R₄, R₅, and R₆ are each independently selected from hydrogen and an alkyl group with substituted or unsubstituted carbons.

14. The method of claim 12, wherein the crosslinker is selected from the following formulas: 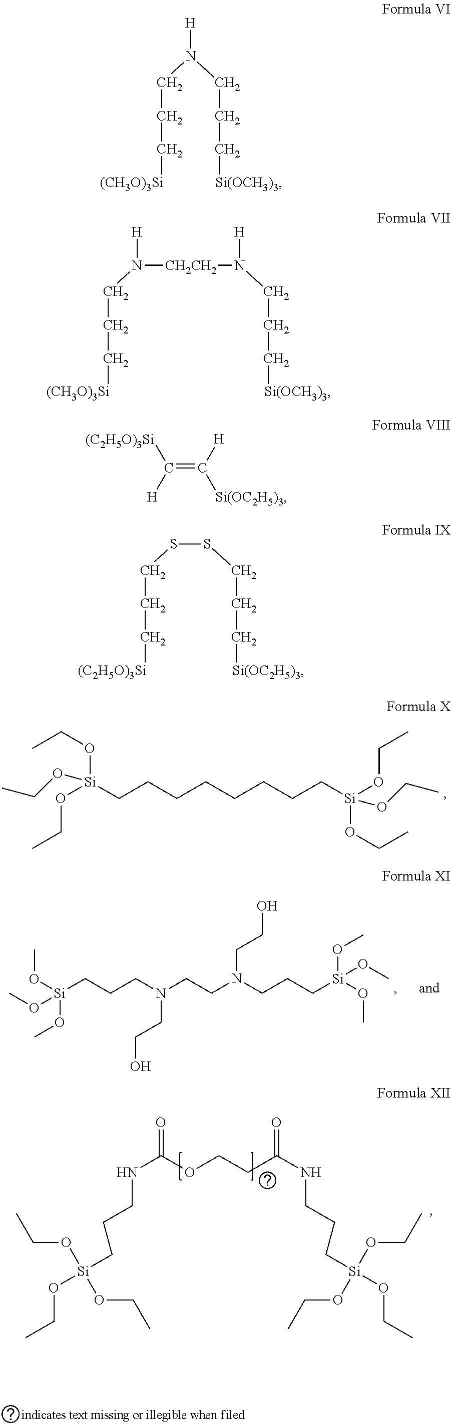
and combinations of the foregoing.

15. The method of claim 12, wherein applying the composition further comprises spin-coating the composition within the plurality of channels in the semiconductor substrate at a speed from 100 rpm to 500 rpm over a time period from 2 seconds to 60 seconds.

16. The method of claim 15, further comprising the additional step, after the applying step, of further spinning the substrate at a speed from 200 to 3000 rpm over a time period from 2 seconds to 60 seconds.

17. The method of claim 12, wherein curing the composition further comprises curing the composition at a temperature from 160° C. to 400° C. over a time period from 60 seconds to 60 minutes.

18. The method of claim 12, further comprising the additional step, prior to the applying step, of depositing a liner coating within the channels of the substrate.

19. The method of claim 12, further comprising the additional step, after the curing step, of depositing an overcoat over the plurality of channels in the substrate.

20. The method of claim 12, wherein the coating has a thickness from 1 μm to 100 μm within the plurality of channels of the substrate.
